(19) United States
(12) Patent Application Publication
(10) Pub. No.: US 2002/0119677 A1
(43) Pub. Date: Aug. 29, 2002

(54) Semiconductor device manufacturing method

(76) Inventors: Eiichi Soda, Tokyo (JP); Ken Tokashiki, Tokyo (JP); Atsushi Nishizawa, Tokyo (JP); Hidetaka Nanbu, Tokyo (JP)

Correspondence Address: McGinn & Gibb, PLLC, Suite 200, 8321 Old Courthouse Road, Vienna, VA, 22182-3817, US

(21) Appl. No.: 10/082,109

(22) Filed: Feb. 26, 2002

(30) Foreign Application Priority Data
Feb. 27, 2001 (JP) 52742/2001

(51) Int. Cl. H01L 21/469

(52) U.S. Cl. 438/780

(57) ABSTRACT

A semiconductor device manufacturing method according to the invention includes a process for forming an insulating film made of organic material the dielectric constant of which is low and which has a relative dielectric constant lower than that of silicon oxide on a semiconductor substrate, a process for forming a resist film having an opening on the insulating film, a process for dry-etching the insulating film using the resist film as a mask and a process for removing at least a part of the resist film by ashing using the plasma of mixed gas including nitrogen and hydrogen.

### BACKGROUND OF THE INVENTION

1. Field of the Invention

The present invention relates to a semiconductor device manufacturing method, particularly relates to a method of manufacturing a semiconductor device including a film the dielectric constant of which is low.

2. Description of the Prior Art

Recently, technique utilizing material the dielectric constant of which is low for reducing capacity between wiring is actively discussed in response to demands for the high-speed operability of a device.

Referring to drawings, a process for forming damascene copper wiring using material the dielectric constant of which is low will be described below.

First, a process shown in FIG. 4A is executed. First, after an insulating film 10 and an interlayer insulating film 12 are formed on a silicon wafer (not shown) in this order, a wiring groove patterned in a predetermined shape by selective dry etching is formed. Next, a barrier metal film and a seed copper film are formed on the whole surface and next, a copper film is formed by plating. Next, the surface of the wafer is polished by chemical mechanical polishing (CMP) and copper wiring 17 is formed. A copper diffusion preventing film 18 is formed on the copper wiring 17 and an interlayer insulating film 19 made of methyl sil-sesquioxane (hereinafter called MSQ) is formed on the copper diffusion preventing film. After resist 30 having a predetermined opening is formed on the interlayer insulating film 19, the interlayer insulating film 19 is dry-etched using the resist as a mask. FIG. 4A shows a state after these are finished.

Next, ashing is performed to remove the resist 30 (FIG. 4B). Ashing is performed by plasma processing using gas including oxygen. Temperature is ordinarily approximately 200 to 250° C.

Afterward, after the copper diffusion preventing film 18 is etched and the copper wiring 17 is exposed at the bottom of a hole (FIG. 4C), metal such as copper and tungsten is buried in a connecting hole by a damascene process and an interlayer connection plug 27 is formed (FIG. 4D).

However, in this process, in ashing, oxygen reacts with an organic functional group which is material for an interlayer insulating film, as a result, the connecting hole has an overhang as shown in FIG. 4B, the interlayer insulating film 19 is converted and a dielectric constant may rise.

An example of a single damascene process is described above, however, there is also a similar problem in case a process for burying in a wiring groove and a connecting hole at a time, so-called dual damascene process is applied. In the dual damascene process, first, after a copper diffusion preventing film 20 and an interlayer insulating film 21 are formed on the interlayer insulating film 19 in this order (FIG. 5A), a reflection reducing film 29 and resist 30 are formed on them in this order, a predetermined opening for etching a wiring groove is provided to the reflection reducing film 29 and the resist 30, dry etching is performed using the reflection reducing film 29 and the resist 30 as a mask to form a hole and next, the resist and others are removed. As a result, a via hole and a wiring groove are formed (FIG. 5B). However, also in this case, in ashing for removing the resist 30, the wiring groove and the connecting hole have an overhand as shown in FIG. 5B, the interlayer insulating films 19 and 21 are converted and a dielectric constant may rise.

### BRIEF SUMMARY OF THE INVENTION

### Object of the Invention

The object of the invention is to provide a semiconductor device manufacturing method of forming a connecting hole and a wiring groove without impairing a dielectric characteristic of organic material the dielectric constant of which is low.

### SUMMARY OF THE INVENTION

A semiconductor device manufacturing method according to the invention includes a process for forming an insulating film made of organic material the relative dielectric constant of which is lower than that of silicon oxide on a semiconductor substrate, a process for forming a resist film having an opening on the insulating film, a process for dry-etching the insulating film using the resist film as a mask and a process for removing at least a part of the resist film by ashing using mixed gas plasma including nitrogen and hydrogen.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIGS. 1A and 1B show a process of a semiconductor device manufacturing method according to the invention;

FIGS. 2A to 2D show a process of the semiconductor device manufacturing method according to the invention;

FIGS. 3A and 3B show a process of the semiconductor device manufacturing method according to the invention;

FIGS. 4A to 4D show a process of a conventional type semiconductor device manufacturing method;

FIGS. 5A and 5B show a process of the conventional type semiconductor device manufacturing method;

FIGS. 6A and 6B show a process of the semiconductor device manufacturing method according to the invention;

FIG. 7 shows ashing equipment used in an embodiment;

FIG. 8 shows the structure of MSQ; and

FIG. 9 shows the effect of the density of hydrogen in plasma gas upon the survival rate of a methyl group.

### DETAILED DESCRIPTION OF THE INVENTION

An insulating film in the invention is made of organic material the dielectric constant of which is lower than that of silicon oxide. It is desirable that material the relative dielectric constant of which is 3.5 or less is used, it is preferable that material the relative dielectric constant of which is 3.0 or less is used and it is desirable that for example, organopolysiloxane or aromatic organic resin is used.

Organopolysiloxane means polysiloxane having an organic functional group and as it is excellent in a dielectric characteristic and workability, it is desirable that alkyl sil-sesquioxane and hydridoalkylsiloxane are used. For example, it is desirable that MSQ and methylated hydrogen sil-sesquioxane (hereinafter called MHSQ) are used and it is particularly desirable that out of them, MSQ which is superior in a dielectric characteristic and workability is used.

For aromatic organic resin, polyarylether (PAE), divinylsiloxane-bis-benzocyclobutene (BCB) can be given. These have a low relative dielectric constant and the heat resistance is also relatively satisfactory.

The above-mentioned insulating film in the invention can be formed by plasma CVD and spin coating. In a case by plasma CVD, mixed gas of alkylsilane gas and oxidative gas is used for material gas. For alkylsilane gas, monomethylsilane, dimethylsilane, trimethylsilane and tetramethylsilane can be given and these can be individually used or two or more types can be used together. Out of these, trimethylsilane is suitably used. Oxidative gas means gas for oxidizing alkylsilane and the one including oxygen in its molecule is used. For example, oxidative gas can be selected from a group including NO, NO₂, CO, CO₂ and O₂ or gas including two or more can be used. Out of these, as the degree of oxidation is suitable, it is desirable that NO and NO₂ are used. In the meantime, in case a first insulating layer is formed by spin coating, solution in which the material of the layer is dissolved is dropped and applied on a wafer spinned at predetermined rotational speed and next, the layer is formed by multiple-stage heat treatment, drying and solidification.

Referring to the drawings, an example of a semiconductor device manufacturing method according to the invention will be described below.

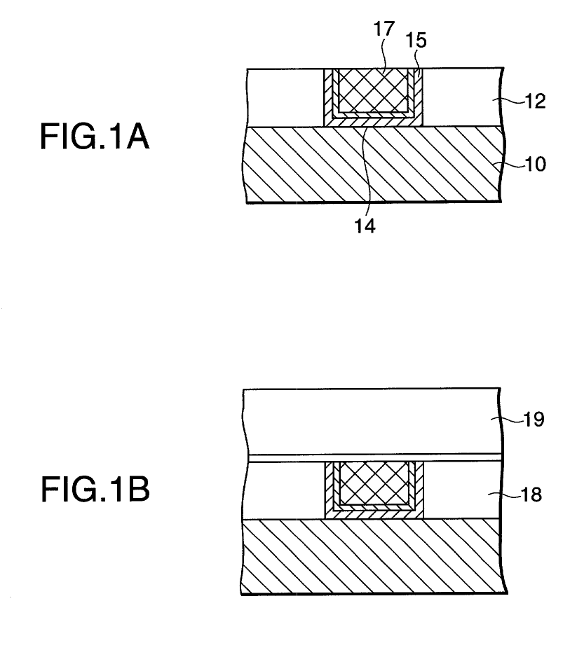

First, copper wiring shown in FIG. 1A is formed, First, after an insulating film 10 and an interlayer insulating film 12 are formed in this order on a silicon wafer, a wiring groove patterned in a predetermined shape is formed by selective dry etching. For the material of the interlayer insulating film 12, in addition to silicon oxide, material the dielectric constant of which is low, for example, polyorganosiloxane such as MSQ and MHSQ or aromatic organic material such as PAE and BCB can be used. Next, after a barrier metal film 14 is deposited on the whole surface by sputtering, a seed copper film 15 is formed by sputtering and next, a copper film is formed by plating. For the material of the barrier metal film 14, metallic material such as Ta, TaN, W, WN, Ti and TiN can be used. In this embodiment, copper is used for wiring material, however, a copper alloy may be also used. A copper alloy means a film including copper by 80 mass percentage or more, desirably 90 mass percentage or more and for the other components, different elements such as Mg, Sc, Zr, Hf, Nb, Ta, Cr and Mo are used.

Next, the surface of the wafer is polished by CMP and as shown in FIG. 1A, copper wiring 17 is formed.

Next, a copper diffusion preventing film 18 is formed on the copper wiring 17. The copper diffusion preventing film means a film for preventing copper from being diffused in the interlayer insulating film and for example, it is made of SiN, SiON, SiC or SiCOH. The copper diffusion preventing film 18 can be formed by plasma CVD.

Next, an interlayer insulating film made of MSQ is formed on it (FIG. 1B). For the material of the interlayer insulating film 19, material the dielectric constant of which is low is desirable and in addition to MSQ, polyorganosiloxane such as MHSQ or aromatic organic material such as PAE and BCB can be used. Parasitic capacity between adjacent wiring can be reduced by using these materials and the operation of the device can be sped up.

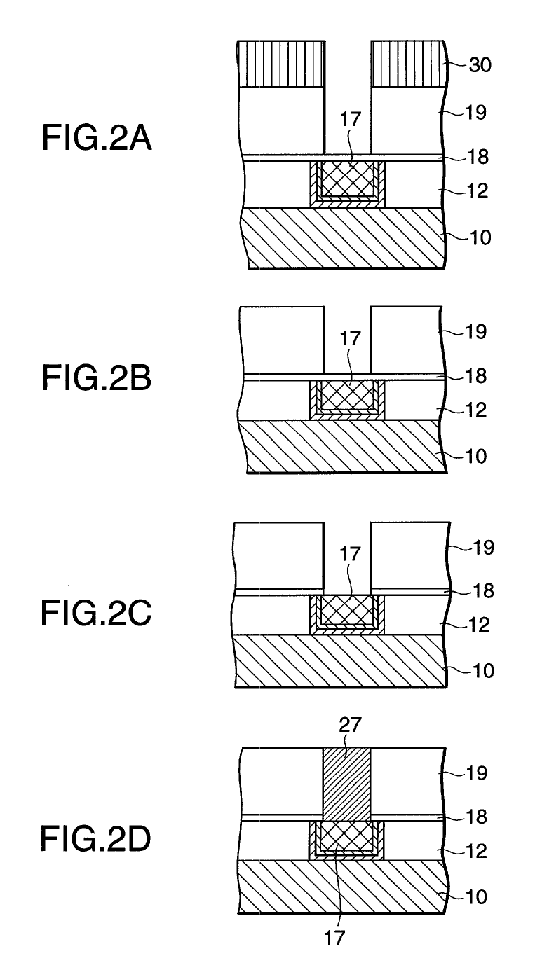

Next, a via hole is formed by dry etching. First, as shown in FIG. 2A, as resist 30 having a predetermined opening is formed on the interlayer insulating film 19, the interlayer insulating film 19 is dry-etched using the resist as a mask. Next, to remove the resist 30, ashing is performed. An example of conditions in plasma processing at this time is as follows.

Hydrogen throughput: 5 to 500 sccm

Nitrogen throughput: 100 to 2000 sccm

Pressure: 0.01 to 10 Torr, desirably 0.01 to 2 Torr

Substrate temperature: −20 to 250° C.

For the desirable throughput ratio (mixture ratio) of hydrogen to nitrogen, it is desirable that the density of hydrogen is 50% or less based upon volume and it is preferable that the density of hydrogen is 20% or less. The lower limit of the density of hydrogen is not particularly defined, however, to enable reduction, it is desirable that the density of hydrogen is 0.1% or more. The interlayer insulating film 19 can be prevented from being converted or damaged by selecting such conditions in plasma processing.

For ashing equipment for ashing, downflow type surface wave plasma ashing equipment, ICP plasma ashing equipment or etching (2-cycle RIE, ICP) equipment may be used.

Afterward, cleaning is performed using a separating agent and the residue of the resist and others are removed (FIG. 2B).

Next, the copper diffusion preventing film 18 is etched using etching gas different from that used in the above-mentioned dry etching as shown in FIG. 2C and the copper wiring 17 is exposed at the bottom of a hole. Afterward, metal such as copper and tungsten is buried in a connecting hole in a damascene process and an interlayer connection plug 27 is formed (FIG. 2D).

According to such a process, as the resist is ashed using mixed gas of hydrogen and nitrogen, the interlayer insulating film 19 is prevented from being damaged in ashing, and the rise of a dielectric constant and the formation of an overhang can be prevented.

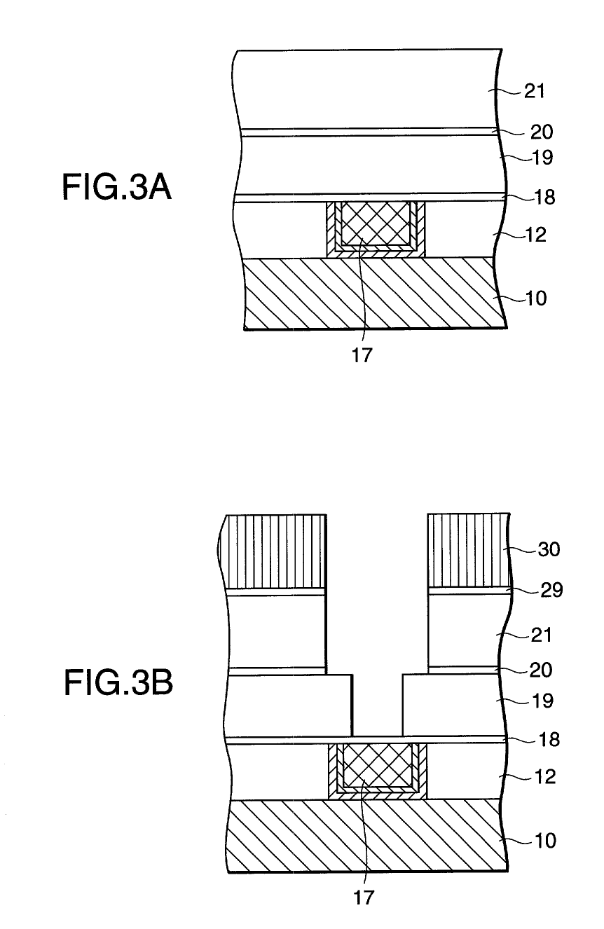

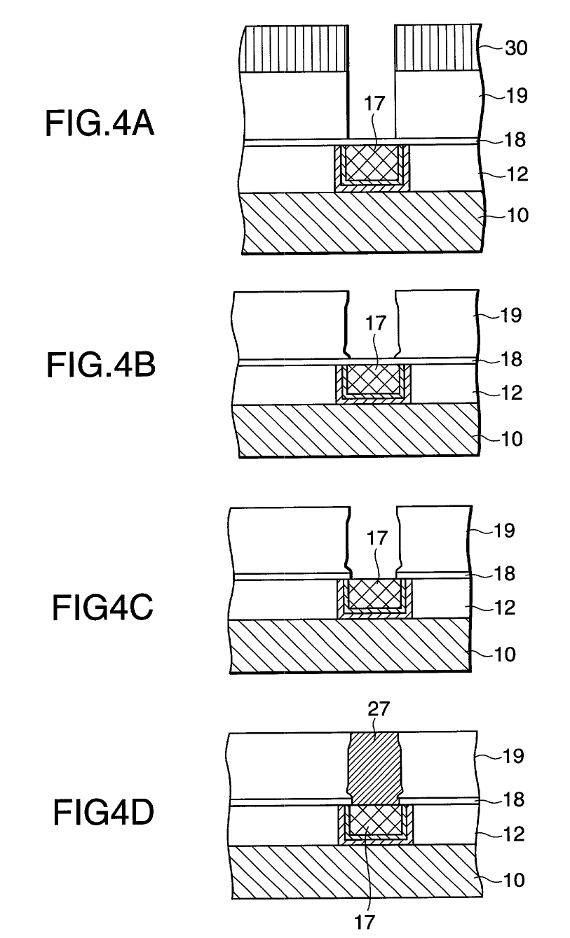

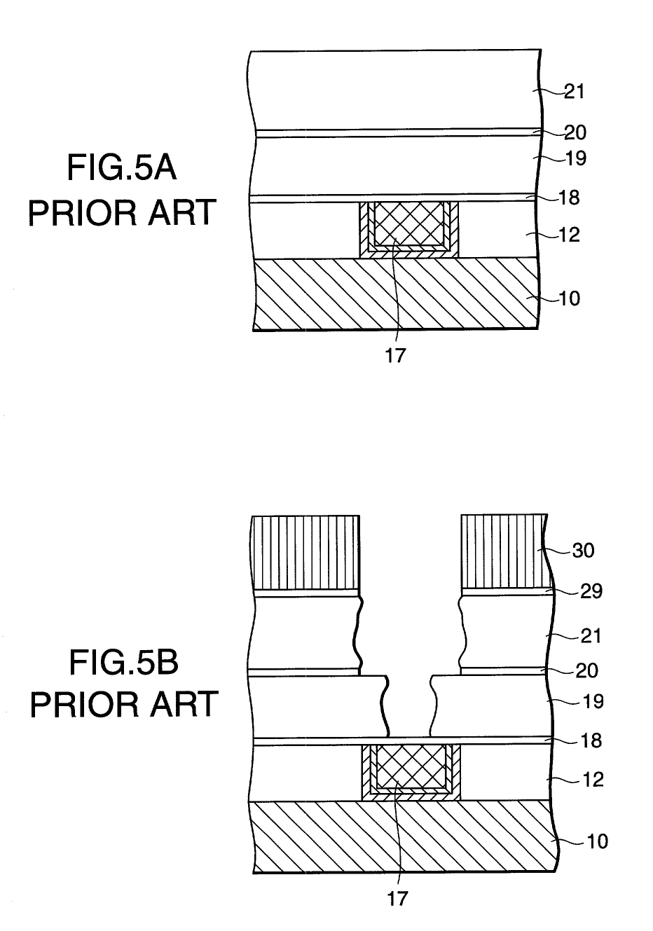

A single damascene process is described above, however, the invention can be also applied to a dual damascene process. Referring to FIG. 3, a dual damascene process will be described below.

First, in the same way as the process up to FIG. 1B, an inter layer insulating film 19 and others are formed. After ward, a copper diffusion preventing film 20 and an interlayer insulating film 21 are formed in this order (FIG. 3A).

Next, resist (not shown) is formed on the interlayer insulating film via a reflection reducing film, after a predetermined opening for etching a wiring groove is provided, a hole is formed by dry etching using the reflection reducing film 29 and the resist 30 as a mask. As a result, a via hole and a wiring groove are formed (FIG. 3).

Next, to remove the resist 30, ashing is performed. An example of conditions in plasma processing at this time is as follows.

Hydrogen throughput: 5 to 500 sccm

Nitrogen throughput: 100 to 2000 sccm

Pressure: 0.01 to 10 Torr, desirably 0.01 to 2 Torr

Substrate temperature: −20 to 250° C.

For the desirable throughput ratio (mixture ratio) of hydrogen to nitrogen, it is desirable that the density of hydrogen is 50% or less based upon volume and it is preferable that the density of hydrogen is 20% or less. The lower limit of the density of hydrogen is not particularly defined, however, to enable reduction, it is desirable that the density of hydrogen is 0.1% or more. The interlayer insulating films 19 and 21 can be prevented from being converted or damaged by selecting such conditions in plasma processing.

Next, cleaning is performed using a separating agent and the residue of the resist and others are removed. Afterward, metal such as metal including copper is buried in the via hole and the wiring groove, and wiring and a via plug are formed.

According to the above-mentioned process, the interlayer insulating films 19 and 21 are prevented from being damaged in ashing, and the rise of a dielectric constant and the formation of an overhang can be prevented. In this embodiment, the connecting hole and the wiring groove are formed by two types of resist masks having different openings, however, a middle first method can be also applied.

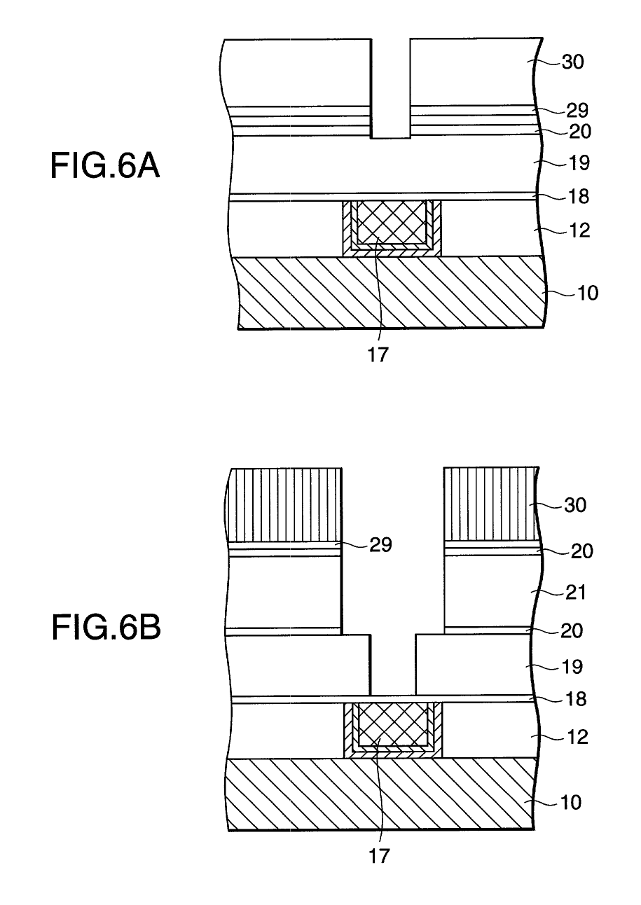

FIG. 6 shows a method of forming dual damascene wiring structure by the middle first method. A copper diffusion preventing film 18 made of SiC is formed by 50 nm on copper wiring 17, an interlayer insulating film 19 made of MSQ is formed by 400 nm, a copper diffusion preventing film 20 made of SiC is formed by 50 nm, a reflection reducing film 29 and resist 30 are applied on it and a via hole 0.18 μm in diameter is exposed and developed. Next, the reflection reducing film 29 and the copper diffusion preventing film 20 are dry-etched using the resist 30 as a mask. Etching is performed in gaseous plasma including CF₄, Ar and O₂ in 2-cycle RIE equipment. After the etching of the copper diffusion preventing film 20, the interlayer insulating film 19 made of MSQ is exposed (FIG. 6A).

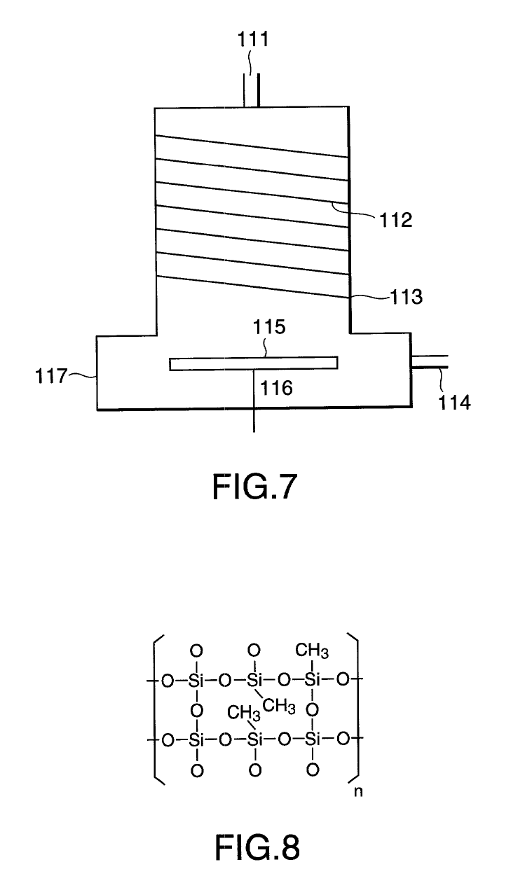

Afterward, the reflection reducing film 29 and the resist 30 are ashed, however, ashing is required to be performed without damaging MSQ. In this embodiment, ashing is performed using ashing equipment shown in FIG. 7. The source of the equipment is inductively coupled plasma (ICP). As shown in FIG. 7, ashing gas is supplied through a gas pipe 111. High-frequency power is supplied from an RF power source 113 and inductively coupled plasma is generated by a coil 112. A processed wafer 115 is put in a vacuum chamber 117 and is fixed on a stage 116. The temperature of the stage 116 is variable (from −20° C. to 250° C.). Plasma reaches to the wafer by down flow and ashing processing is enabled. Are action product and gas after ashing are exhausted through an exhaust pipe 114.

Ashing conditions in this embodiment are as follows.

Pressure: 0.8 Torr

Source power: 400 W

Gas: H₂:35 sccm, N₂:965 sccm (H₂ density: 3.5%)

Temperature: 20° C.

Ashing time: End of emission+over-ashing equivalent to 100%

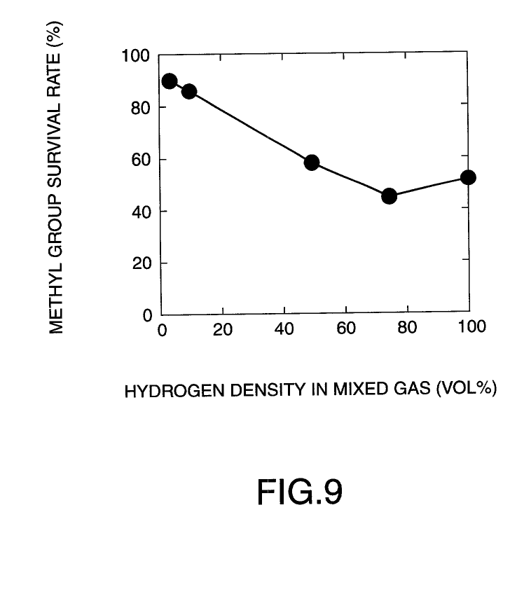

FIG. 8 shows MSQ structure. CH₃ is coupled to Si-O chain and damage to a film made of MSQ by ashing can be evaluated by the survival rate of CH₃. For a reference experiment, after a film made of MSQ 400 nm thick was processed under the above-mentioned ashing conditions for two minutes, the survival rate of CH₃ was estimated based upon the variation of the intensity at a peak (2900 cm⁻¹) of CH₃ on FT-IR. FIG. 9 shows the result. The result shows that the survival rate of a methyl group can be effectively reduced as a result by setting the density of hydrogen to 50 vol-% or less desirably, setting it to 20 vol-% or less preferably and setting it to 10 vol-% or less most desirably. In this embodiment, as the density of hydrogen is set to 3.5 vol-%, the survival rate of CH₃ is 90% and it is known that there is hardly damage. As a result of applying ashing conditions in this embodiment to an actual sample, no overhang was recognized. It was verified that resist was also satisfactorily removed. As a result, it was verified that when the density of H₂ in mixed gas of H₂ and N₂ was 3.5%, resist could be satisfactorily peeled, inhibiting damage to the film made of MSQ. The reason why the density of H₂ is set to 3.5% is that as the density of H₂ is increased, damage to the film increases. It is estimated that the reactivity of N—H and CH₃ increases, CHX is easily generated and as a result, CH₃ is desorbed.

Again, the middle first method shown in FIG. 6 will be described. After ashing, processing by an organic peeling agent is performed. Next, an interlayer insulating film 21 made of MSQ is formed by 400 nm. Further, a copper diffusion preventing film 20′ made of SiC is formed by 50 nm, a reflection reducing film 29 and resist 30 are applied and a groove the L/S of which is 0.20 m/0.20 m is exposed. Next, the reflection reducing film 29, the copper diffusion preventing film 20 and the interlayer insulating film 21 are dry-etched using the resist 30 as a mask. CF₄, Ar or O₂ is used for gas for etching the reflection reducing film 29 and the copper diffusion preventing film 20 and C₄F₈, Ar or N₂ is used for gas for etching the interlayer insulating film 21. The etching of the interlayer insulating film 21 stops at the copper diffusion preventing film 20 and next, structure shown in FIG. 6B is acquired by etching the interlayer insulating film 19. Next, the reflection reducing film 29 and the resist 30 are ashed under the following conditions.

Pressure: 0.8 Torr

Source power:400 W

Gas: H₂:35 sccm, N₂:965 sccm (H₂ density: 3.5%)

Temperature: 20° C.

The groove and the hole produced as described above had no overhang and the shape according to the design was acquired. The resist was satisfactorily removed.

As described above, according to the invention, as the resist is removed by ashing using plasma using mixed gas including nitrogen and hydrogen, the damage and conversion of the organic material the dielectric constant of which is low can be effectively prevented.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A semiconductor device manufacturing method, comprising:
a process for forming an insulating film made of organic material the dielectric constant of which is low and which has a relative dielectric constant lower than that of silicon oxide on a semiconductor substrate;
a process for forming a resist film having an opening on the insulating film;
a process for dry-etching the insulating film using the resist film as a mask; and
a process for removing at least a part of the resist film by ashing using the plasma of mixed gas including nitrogen and hydrogen.

2. A semiconductor device manufacturing method according to claim 1, wherein:
the density of hydrogen in the mixed gas including nitrogen and hydrogen is in a range of 0.1 to 50% based upon volume.

3. A semiconductor device manufacturing method according to claim 1, wherein:
the insulating film is made of organopolysiloxane or aromatic organic resin.

4. A semiconductor device manufacturing method according to claim 1, wherein:
the insulating film is made of methyl sil-sesquioxane or methylated hydrogen sil-sesquioxane.
